(19) United States
(12) Patent Application Publication
(10) Pub. No.: US 2025/0116928 A1
(43) Pub. Date: Apr. 10, 2025

(54) SUBSTRATE COATING RESIST COMPOSITION AND METHOD FOR MANUFACTURING RESIST PATTERN

(71) Applicant: MERCK PATENT GMBH, DARMSTADT (DE)

(72) Inventors: MASAHIKO KUBO, KAKEGAWA (JP); TETSUMASA TAKAICHI, KAKEGAWA (JP)

(21) Appl. No.: 18/954,045

(22) Filed: Nov. 20, 2024

Related U.S. Application Data
(63) Continuation of application No. PCT/EP2023/063208, filed on Aug. 17, 2023.

(30) Foreign Application Priority Data
May 20, 2022 (JP) 2022-083034
Aug. 24, 2022 (JP) 2022-133626

(51) Int. Cl. G03F 7/004; G03F 7/038

(52) U.S. Cl. CPC G03F 7/0045; G03F 7/0382

(57) ABSTRACT

Provided is a substrate coating resist composition containing a polymer (A) having a specific structure as defined herein and a photoacid generator (B) having a specific structure as defined herein.

### CROSS-REFERENCE TO RELATED APPLICATIONS

This application is a Continuation under 35 USC § 111(a) of International Patent Application No. PCT/EP2022/063208, filed May 17, 2023, which claims benefit of Japanese Application No. 2022-083034, filed May 20, 2022 and Japanese Application No. 2022-133626, filed Aug. 24, 2022. The entire contents of these applications are incorporated herein by reference in their entirety.

### BACKGROUND OF THE INVENTION

### Field of the Invention

The present invention relates to a substrate coating resist composition and a method for manufacturing a resist pattern.

### Background Art

In recent years, there has been an increased need for high integration of LSI, and refinement of patterns is required. In order to respond such needs, lithography processes using a KrF excimer laser (248 nm), a ArF excimer laser (193 nm), extreme ultraviolet (EUV; 13 nm), X-ray of short wavelength, an electron beam or the like have been put to practical use. In order to respond to such refinement of resist patterns, also for photosensitive resin compositions to be used as a resist during refinement processing, those having high resolution are required. Finer patterns can be formed by exposing with light of a short wavelength, but high dimensional accuracy is required.

In the lithography process, a resist pattern is formed by exposing and developing the resist. The phenomenon in which at the time of exposure, the incident light on the resist and the reflected light from the substrate or the air interface interfere with each other to generate standing wave is known. The generation of standing wave reduces the pattern dimensional accuracy. Attempts have been made to form an anti-reflective coating on the top layer and/or bottom layer of the resist to reduce standing wave. A bottom anti-reflective coating can reduce the influence of reflection from a substrate, and thus has a large effect of reducing standing wave. However, when the bottom anti-reflective coating is formed, a step of removing the bottom anti-reflective coating is required, and thus the bottom anti-reflective coating may not be suitable depending on a subsequent processing step, and there is a demand for reducing standing wave without forming the bottom anti-reflective coating since it is desired to further simplify manufacturing processes.

It has been proposed that, by including an organic compound in a lithography component such as a resist, for example, a moving speed of an acid generated by an acid generator is suppressed, and standing wave is reduced. See WO 2022/023230A.

### BRIEF DESCRIPTION OF THE DRAWINGS

FIG. 1 is a conceptual diagram illustrating a cross-sectional shape of a negative type resist pattern when affected by standing wave.

FIG. 2 is a conceptual diagram illustrating a cross-sectional shape of a negative type resist pattern when not affected by standing wave.

FIG. 3 is a conceptual diagram illustrating a cross-sectional shape of a trench pattern.

FIG. 4 is a conceptual diagram illustrating a cross-sectional shape of trench patterns having different Wt/Wb.

### SUMMARY OF THE INVENTION

### Problems to be Solved by the Invention

The present inventors have considered that there are one or more objectives that still need improvements in the resist composition. These problems are, for example, as follows. When the bottom anti-reflective coating is not formed, the effect of reducing standing wave in the resist pattern is low; the resist pattern width is non-uniform; the rectangularity of the resist pattern is low; the resolution of the resist pattern is low; the heat resistance of the resist pattern is low; and the efficiency of the manufacturing process is low.

### Means for Solving the Problems

The present inventors surprisingly found that standing wave can be reduced by increasing the diffusion of the acid of the photoacid generator contained in the resist composition.

The present invention provides a substrate coating resist composition that includes:
a polymer (A) and a photoacid generator (B), in which the polymer (A) includes at least one of repeating units represented by Formulae (A-1) and (A-2), and optionally further includes at least one of repeating units represented by Formulae (A-3) and (A-4), and
   the photoacid generator (B) is represented by Formula (B-1),

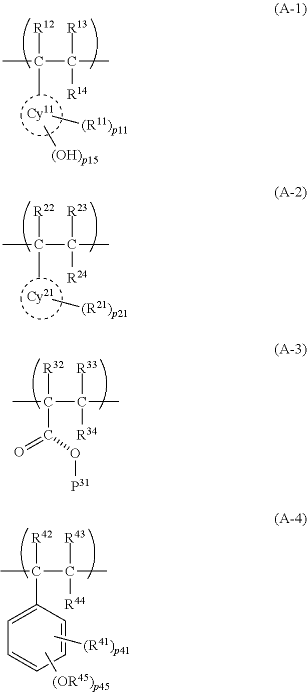

wherein
   Cy¹¹ and Cy²¹ are each independently aryl or heteroaryl having 5 or 6 ring atoms,
   R¹¹, R²¹, R⁴¹, and R⁴⁵ are each independently C₁₋₅ alkyl (wherein methylene in the alkyl can be replaced with oxy);
   R¹², R¹³, R¹⁴, R²², R²³, R²⁴, R³², R³³, R³⁴, R⁴², R⁴³, and R⁴⁴ are each independently hydrogen, C₁₋₅ alkyl, C₁₋₅ alkoxy, or —COOH;
   p11 is 0 to 4, p15 is 1 to 2, p11+p15≤5,
   p21 is 0 to 5,
   p41 is 0 to 4, p45 is 1 to 2, p41+p45≤5; and
   P³¹ is C₄₋₂₀ alkyl, wherein some or all of alkyl can form a ring, some or all of H of the alkyl can be substituted with halogen, and methylene in the alkyl can be replaced with oxy or carbonyl,
   Bⁿ⁺ cation Bⁿ⁻ anion (B-1) wherein
   Bⁿ⁺ cation is n-valent as a whole, Bⁿ⁻ anion is n-valent as a whole, n is 1 to 3, and
   Bⁿ⁻ anion is an anion represented by Formula

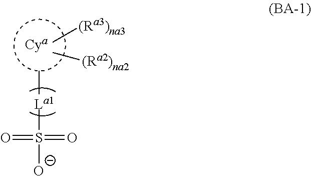

(BA1), and
wherein
   C_{y}^{a} is a hydrocarbon ring having 5 or 6 ring atoms, and one of the ring atoms can be replaced with nitrogen,
   L^{a1} is C₁₋₅ alkylene,
   R^{a2} is nitro or cyano,
   R^{a3} is unsubstituted or fluorine-substituted C₁₋₁₀ alkyl,
   na1 is 0 or 1,
   na2 is a number of 0 to 3, and
   na3 is a number of 0 to 3.

A method for manufacturing a resist pattern according to the present invention includes:
(1) applying the above-described composition directly onto a substrate;
(2) heating the composition to form a resist layer;
(3) exposing the resist layer;
(4) post exposure baking the resist layer; and
(5) developing the resist layer.

A method for manufacturing a device according to the present invention includes the above-described method.

### Effects of the Invention

According to the present invention, it is possible to expect one or more of the following effects. Even when the bottom anti-reflective coating is not formed, the effect of reducing standing wave in the resist pattern is high; the resist pattern width is uniform; the rectangularity of the resist pattern is high; the resolution of the resist pattern is high; the heat resistance of the resist pattern is high; and the efficiency of the manufacturing process is high.

### DETAILED DESCRIPTION OF THE INVENTION

### Mode for Carrying Out the Invention

Embodiments of the present invention are described below in detail.

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “Cx-y”, “Cx-Cy” and “Cx” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plurality of types of repeating units, these repeating units copolymerize. These copolymerization are any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (C) or another component.

### Substrate Coating Resist Composition

A substrate coating resist composition of the present invention (hereinafter, referred to as the composition) contains a polymer (A) and a photoacid generator (B).

In the present invention, the substrate coating resist composition refers to a resist composition that coats a substrate without interposing a bottom anti-reflective coating. The substrate in the present invention can be a single layer or a laminate, and a structure such as a groove can be formed.

The composition according to the present invention is preferably a substrate coating chemically amplified resist composition, and more preferably a substrate coating chemically amplified KrF resist composition.

The composition according to the present invention can also be used for both a positive type and a negative type. In a preferred embodiment of the present invention, the composition according to the present invention is a substrate coating chemically amplified positive type KrF resist composition. In another preferred embodiment of the present invention, the composition according to the present invention is a substrate coating chemically amplified negative type KrF resist composition.

### Polymer (A)

The composition according to the present invention contains a polymer (A) (hereinafter, referred to as the component (A); the same applies to other components). The polymer (A) includes at least one of repeating units represented by Formulae (A-1) and (A-2), and optionally further includes at least one of repeating units represented by Formulae (A-3) and (A-4). More preferably, the polymer (A) includes the repeating unit represented by Formula (A-1), and further includes at least one of the repeating units represented by Formulae (A-3) and (A-4).

Formula (A-1) is as follows:

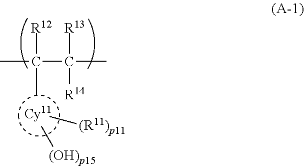

wherein
   Cy¹¹ is each independently aryl or heteroaryl having 5 or 6 ring atoms, preferably benzene.
   R¹¹ is each independently C₁₋₅ alkyl (wherein methylene in the alkyl can be replaced with oxy), preferably methyl or ethyl, more preferably methyl. In the present invention, the expression “methylene in the alkyl can be replaced with oxy” means that oxy can be present between carbon atoms in the alkyl, and it is not intended that the terminal carbon in the alkyl becomes oxy, i.e., it is not intended to have alkoxy or hydroxy.
   R¹², R¹³, and R¹⁴ are each independently hydrogen, C₁₋₅alkyl, C₁₋₅alkoxy or —COOH, preferably hydrogen or methyl, more preferably hydrogen.
   p11 is 0 to 4, preferably 0 or 1, more preferably 0.
   p15 is 1 to 2, preferably 1. Provided that, p11+p15≤5 is satisfied.

The polymer (A) can include a plurality of types of repeating units represented by Formula (A-1). For example, it is possible for the polymer (A) to have a structural unit of p15=1 and a structural unit of p15=2 at a ratio of 1:1. In this case, it becomes p15=1.5 as a whole. Hereinafter, unless otherwise specified, the same applies to the numbers for representing polymer in the present invention.

Specific examples of Formula (A-1) includes the following:

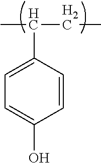

Formula (A-2) is as follows:

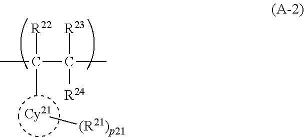

wherein
   C_{y}²¹ is each independently aryl or heteroaryl having 5 or 6 ring atoms, preferably benzene.
   R²¹ is each independently C₁₋₅ alkyl (wherein methylene in the alkyl can be replaced with oxy), preferably methyl, ethyl, t-butyl or t-butoxy, more preferably methyl or ethyl, further preferably methyl.
   R²², R²³ and R²⁴ are each independently hydrogen, C₁₋₅alkyl, C₁₋₅alkoxy or —COOH, preferably hydrogen or methyl, more preferably hydrogen.
   p21 is 0 to 5, preferably 0, 1, 2, 3, 4 or 5, more preferably 0 or 1, further preferably 0.

Specific examples of Formula (A-2) includes the following:

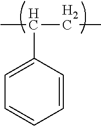

Formula (A-3) is as follows:

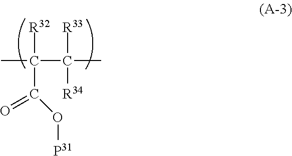

wherein
   R³², R³³, and R³⁴ are each independently hydrogen, C₁₋₅alkyl, C₁₋₅alkoxy or —COOH; preferably hydrogen, methyl, ethyl, t-butyl, methoxy, t-butoxy or —COOH; more preferably hydrogen or methyl; further preferably hydrogen.
   P³¹ is C₄₋₂₀ alkyl. Some or all of alkyl can form a ring, some or all of H of the alkyl can be substituted with halogen, and methylene in the alkyl can be replaced with oxy or carbonyl. Some or all of alkyl can form a ring, some or all of H of the alkyl can be substituted with halogen, and methylene in the alkyl can be replaced with oxy or carbonyl. The alkyl moiety of P³¹ is preferably branched or cyclic. When the C₄₋₂₀ alkyl in P³¹ is replaced with halogen, it is preferable that all are replaced, and the halogen that replaces is preferably F or Cl, more preferably F. It is a preferred embodiment of the present invention that H of the C₄₋₂₀ alkyl in P³¹ is not replaced with any halogen. P³¹ is preferably methyl, isopropyl, t-butyl, cyclopentyl, methylcyclopentyl, ethylcyclopentyl, cyclohexyl, methylcyclohexyl, ethylcyclohexyl, adamantyl, methyladamantyl or ethyladamantyl, more preferably t-butyl, ethylcyclopentyl, ethylcyclohexyl or ethyladamantyl, further preferably t-butyl, ethylcyclopentyl or ethyladamantyl, further more preferably t-butyl.

Specific examples of Formula (A-3) include the following:

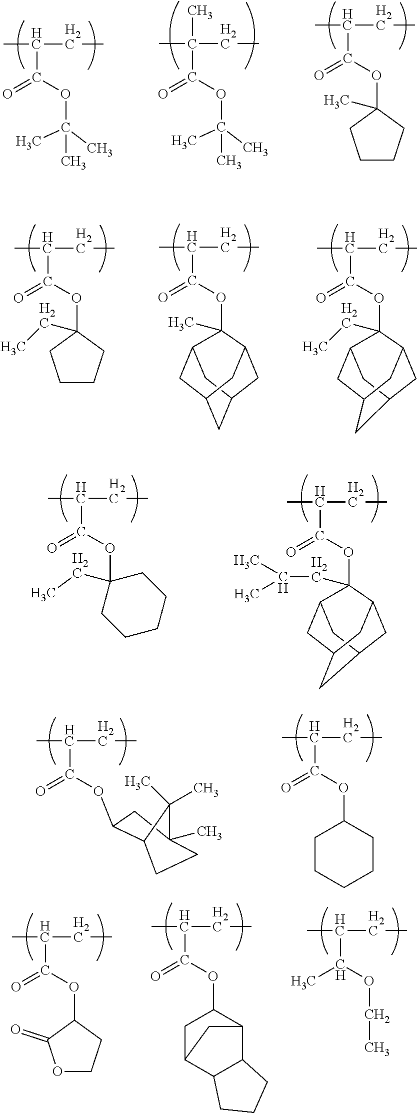

Formula (A-4) is as follows:

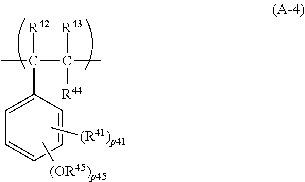

wherein
   R⁴¹ is each independently C₁₋₅ alkyl (wherein methylene in the alkyl can be replaced with oxy), preferably methyl, ethyl or t-butyl, more preferably methyl.
   R⁴⁵ is each independently C₁₋₅ alkyl (wherein methylene in the alkyl can be replaced with oxy), preferably methyl, t-butyl or —CH(CH₃)—O—CH₂CH₃.
   R⁴², R⁴³, and R⁴⁴ are each independently hydrogen, C₁₋₅alkyl, C₁₋₅alkoxy or —COOH, preferably hydrogen or methyl, more preferably hydrogen.
   p41 is 0 to 4, more preferably 0 or 1, further preferably 0.
   p45 is 1 to 2, more preferably 1.
   p41+p45≤5 is satisfied.
      Specific examples of Formula (A-4) include the following:

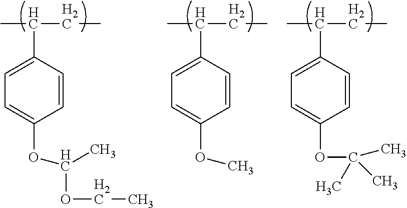

n_{A-1}, n_{A-2}, n_{A-3} and n_{A-4}, which are the numbers of repeating units represented by Formulae (A-1), (A-2), (A-3) and (A-4) in the polymer (A), are described below.
n_{A-1}/(n_{A-1}+n_{A-2}+n_{A-3}+n_{A-4}) is preferably 0 to 100%, more preferably 50 to 80%, further preferably 55 to 75%, and further more preferably 55 to 65%.
n_{A-2}/(n_{A-1}+n_{A-2}+n_{A-3}+n_{A-4}) is preferably 0 to 100%, more preferably 0 to 30%, further preferably 5 to 25%, and further more preferably 15 to 25%.
n_{A-3}/(n_{A-1}+n_{A-2}+n_{A-3}+n_{A-4}) is preferably 0 to 50%, more preferably 10 to 40%, further preferably 15 to 35%, and further more preferably 15 to 25%.
n_{A-4}/(n_{A-1}+n_{A-2}+n_{A-3}+n_{A-4}) is preferably 0 to 50%, more preferably 0 to 30%, further preferably 0 to 10%, and further more preferably 0 to 5%. It is also a preferred embodiment of the present invention that n_{A-4} is 0. A preferred embodiment includes the following: n_{A-1}/(n_{A-1}+n_{A-2}+n_{A-3}+n_{A-4})=40 to 80%, n_{A-2}/(n_{A-1}+n_{A-2}+n_{A-3}+n_{A-4})=0 to 40%, n_{A-3}/(n_{A-1}+n_{A-2}+n_{A-3}+n_{A-4})=10 to 50%, and n_{A-4}/(n_{A-1}+n_{A-2}+n_{A-3}+n_{A-4})=0 to 40%.

The polymer (A) can also include an additional repeating unit other than the repeating units represented by Formulae (A-1), (A-2), (A-3) and (A-4). nₜₒₜₐₗ, which is the total number of all repeating units included in the polymer (A), satisfies the following:

(n_{A-1}+n_{A-2}+n_{A-3}+n_{A-4})/nₜₒₜₐₗ=preferably 80 to 100%, more preferably 90 to 100%, and further preferably 95 to 100%. It is also a preferred embodiment of the polymer (A) to include no further repeating unit.

When the composition according to the present invention is a positive type resist composition, specific examples of the polymer (A) include the following:

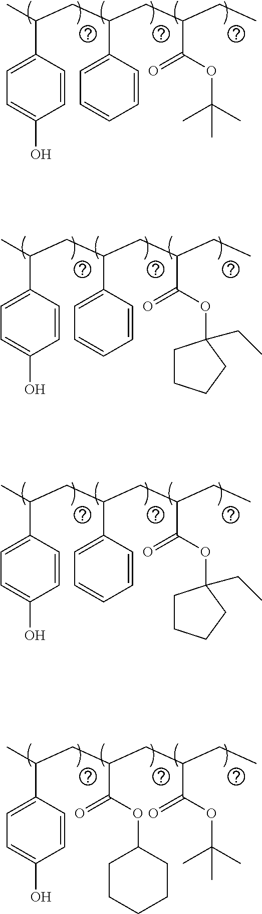

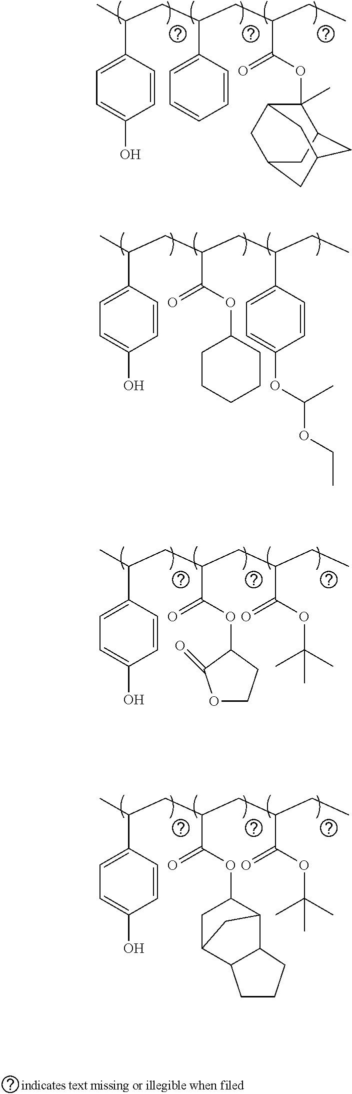

When the composition according to the present invention is a negative type resist composition, specific examples of the polymer (A) include the following:

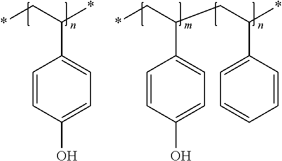

The mass average molecular weight (hereinafter, referred to as Mw) of the polymer (A) is 3,000 to 50,000, more preferably 4,000 to 20,000, further preferably 10,000 to 19,000, and further more preferably 11,000 to 13,000. Without wishing to be bound by theory, it is thought that due to the polymer (A) having this Mw, it becomes possible to form a resist pattern with good rectangularity or resolution from the composition of the present invention. In the present invention, Mw can be measured by gel permeation chromatography (GPC). In the measurement, it is a preferable example that a GPC column at 40 degrees Celsius, an elution solvent of tetrahydrofuran at 0.6 mL/min and monodisperse polystyrene as a standard are used.

The content of the polymer (A) is preferably 10 to 40 mass %, more preferably 12 to 38 mass %, further preferably 15 to 36 mass %, based on the total mass of the composition.

The composition according to the present invention can contain a polymer other than the polymer (A), but an embodiment in which no polymer other than the polymer (A) is one preferred embodiment.

### Photoacid Generator (B)

The composition according to the present invention contains a photoacid generator (B) represented by Formula (B-1).

The composition according to the present invention has the effect of reducing standing wave. Without wishing to be bound by theory, the reason for this is considered to be as follows.

The anion of the photoacid generator (B) is an anion represented by Formula (BA-1) as described below, which contains a hydrocarbon ring having 5 or 6 ring atoms. The polymer (A) includes at least one of the repeating units represented by Formulae (A-1) and (A-2), and these contain an aryl or heteroaryl group.

Each anion of the photoacid generator (B) has a ring structure as described above, and thus has the same structure as that of the polymer (A). When the acid thermally diffuses in the polymer, the energy barrier for the diffusion is lowered, and the transfer of protons is not hindered. As a result, it is considered that the diffusion distance of the acid is increased, thereby serving to counteract the influence of standing wave of the pattern sidewall, and making the pattern sidewall portion have a smooth shape.

Formula (B-1) is as follows:
Bⁿ⁺ cation Bⁿ⁻ anion (B-1) wherein
Bⁿ⁺ cation is n-valent as a whole, Bⁿ⁻ anion is n-valent as a whole, n is 1 to 3.
Bⁿ⁻ anion is an anion represented by Formula (BA-1).

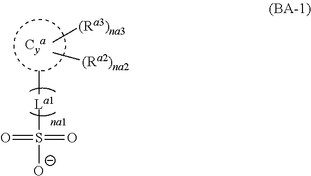

wherein
C_{y}^{a} is a hydrocarbon ring having 5 or 6 ring atoms, and one of the ring atoms can be replaced with nitrogen, preferably benzene, pyridine, or pyrrole.
L^{a1} is C₁₋₅ alkylene, preferably C₁₋₃ alkylene, more preferably ethylene.
R^{a2} is nitro or cyano, preferably nitro.
R^{a3} is unsubstituted or fluorine-substituted C₁₋₁₀ alkyl, preferably unsubstituted or fluorine-substituted C₁₋₈ alkyl.
na1 is 0 or 1.
na2 is a number of 0 to 3, preferably 0 or 1.
na3 is a number of 0 to 3, preferably 0, 1, or 2.

Specific examples of the anion represented by Formula (BA-1) includes the following:

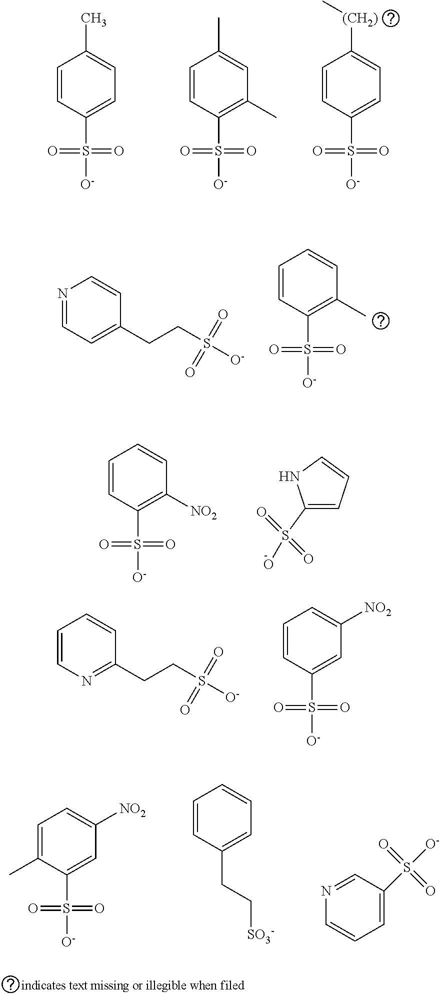

More preferably, the Bⁿ⁻ anion is represented by Formula (BA-1a).

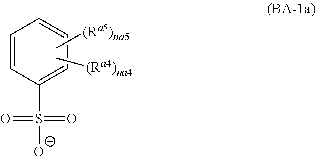

wherein
   R^{a4} is nitro.
   R^{a5} is unsubstituted or fluorine-substituted C₁₋₃ alkyl, preferably unsubstituted or fluorine-substituted methyl, more preferably methyl.
   na4 is 0 or 1.
   na5 is 0, 1, or 2.
   The Bⁿ⁺ cation is not particularly limited as long as it is usually used as a cation of the photoacid generator, but is preferably selected from the group consisting of a cation represented by Formula (BC-1), a cation represented by Formula (BC-2), and a cation represented by Formula (BC-3), and is preferably a cation represented by Formula (BC-1).

Formula (BC-1) is as follows:

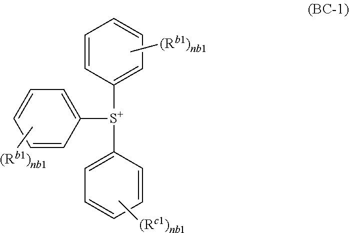

wherein
   R^{b1} is each independently C₁₋₆ alkyl, C₁₋₆ alkoxy, C₆₋₁₂ aryl, C₆₋₁₂ arylthio or C₆₋₁₂ aryloxy, preferably methyl, ethyl, t-butyl, methoxy, ethoxy, phenylthio or phenyloxy, more preferably t-butyl, methoxy, ethoxy, phenylthio or phenyloxy.
   nb1 is each independently 0, 1, 2, or 3, preferably 0 or 1, more preferably 0.

Specific examples of Formula (BC1) include the following:

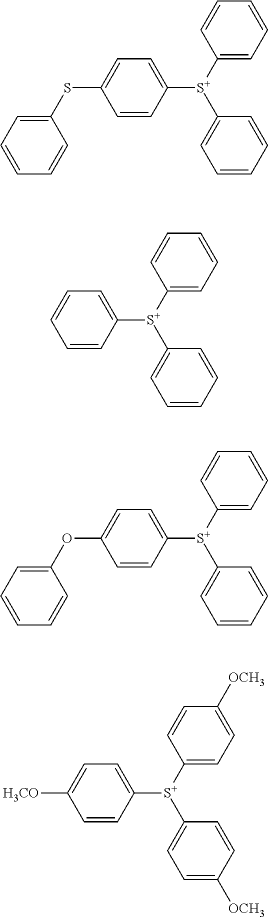 [SMILES: c1ccc(Sc2ccc([S+](c3ccccc3)c3ccccc3)cc2)cc1 ; c1ccc([S+](c2ccccc2)c2ccccc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1]

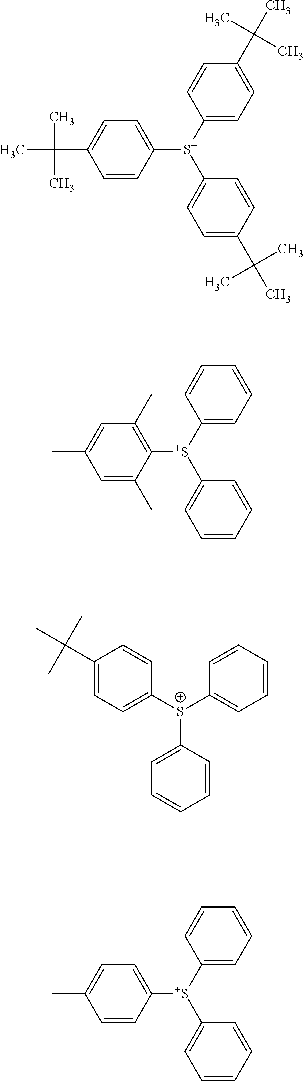

Formula (BC-2) is as follows:

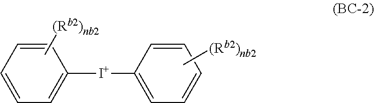

wherein
   R^{b2} is each independently C₁₋₆ alkyl, C₁₋₆ alkoxy or C₆₋₁₂ aryl, preferably alkyl having a C₄₋₆ branched structure. R^{b2} in the formula can be the same as or different from each other, and one in which they are the same as each other is more preferable. R^{b2} is further preferably t-butyl or 1,1-dimethylpropyl, further more preferably t-butyl.
   nb2 is each independently 0, 1, 2, or 3, preferably 1.

Specific examples of Formula (BC2) include the following:

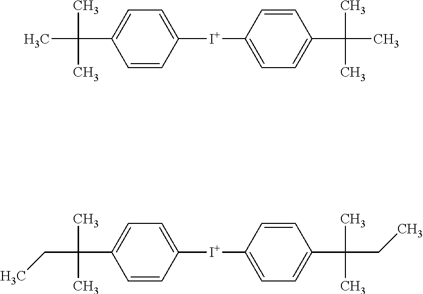

Formula (BC-3) is as follows:

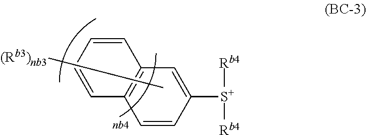

wherein
   R^{b3} is each independently hydroxy, C₁₋₆ alkyl, C₁₋₆ alkoxy or C₆₋₁₂ aryl, preferably methyl, ethyl, methoxy or ethoxy, more preferably methyl or methoxy.
   R^{b4} is each independently C₁₋₆ alkyl, preferably methyl, ethyl, propyl or butyl. Two R^{b4} can be bonded to each other to form a ring structure, and when a ring is formed, it is preferred to form a 5- or 6-membered alicycle.
   nb3 is each independently 0, 1, 2, or 3, preferably 1, 2 or 3, more preferably 1 or 3.
   nb4 is 0 or 1, preferably 0.

Specific examples of Formula (BC3) include the following:

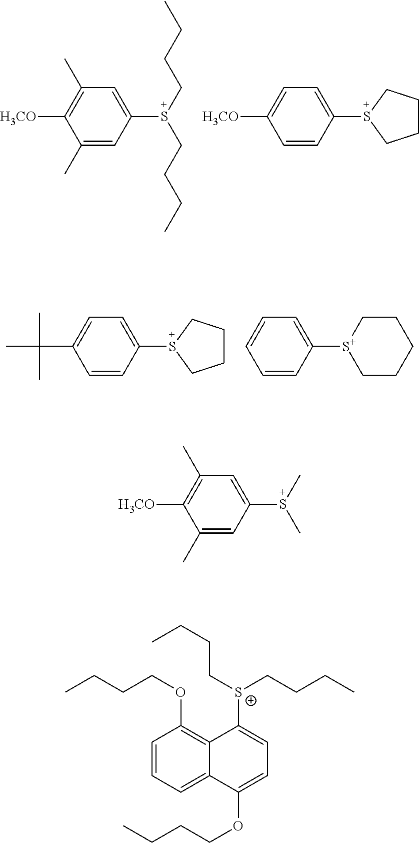

The photoacid generator (B) can also contain fluorine, but it is also a preferred embodiment that the photoacid generator (B) does not contain fluorine in consideration of environmental influence.

The photoacid generator (B) can be one or two or more kinds, but is preferably one or two or more kinds, and more preferably one kind.

The content of the photoacid generator (B) is preferably 0.2 to 5 mass % and more preferably 1 to 4 mass %, based on the total mass of the polymer SOLVENT C

The composition according to the present invention can further contain a solvent (C). The solvent (C) is not particularly limited as long as it can dissolve each component to be mixed. The solvent (C) is preferably water, a hydrocarbon solvent, an ether solvent, an ester solvent, an alcohol solvent, a ketone solvent, or a combination of any of these.

Specific examples of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonanone, cyclohexanone, cyclopentanone, methylcyclohexanone, 2,4-pentanedione, acetonylacetone, diacetone alcohol, acetophenone, fenthion, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of any two or more of these.

The solvent (C) more preferably includes propylene glycol monomethyl ether, propylene glycol monomethyl ether acetate, ethyl lactate, n-butyl acetate, n-butyl ether, 2-heptanone, cyclohexanone, or any combination of any of these, and further preferably propylene glycol monomethyl ether, ethyl lactate, or a mixture of these. When two types are mixed, the mass ratio of a first solvent to a second solvent is preferably 95:5 to 5:95 (more preferably 90:10 to 10:90; further preferably 80:20 to 20:80).

In relation to other layers or films, it is also one embodiment of the present invention that the solvent (C) substantially contains no water. For example, the amount of water in the whole solvent (C) is preferably 0.1 mass % or less, more preferably 0.01 mass % or less, and further preferably 0.001 mass % or less. It is also a preferred embodiment that the solvent (C) contains no water (0 mass %).

The content of the solvent (C) is preferably 50 to 95 mass %, more preferably 60 to 93 mass %, and further preferably 70 to 90 mass %, based on the total mass of the composition. By increasing or decreasing the amount of the solvent occupying in the whole composition, the film thickness after film formation can be controlled.

### Basic Compound (D)

The composition according to the present invention can further contain a basic compound (D). The basic compound (D) has an effect of suppressing environmental influence.

In addition to the above effect, the basic compound also has an effect of suppressing the deactivation of the acid on the film surface due to the amine component contained in the air.

The basic compound (D) is preferably selected from the group consisting of ammonia, C₁₋₁₆ primary aliphatic amine, C₂₋₃₂ secondary aliphatic amine, C₃₋₄₈ tertiary aliphatic amine, C₆₋₃₀ aromatic amine, C₅₋₃₀ heterocyclic amine, and derivatives thereof.

Specific examples of the basic compound (D) include ammonia, ethylamine, n-octylamine, ethylenediamine, triethylamine, triethanolamine, tripropylamine, tributylamine, triisopropanolamine, diethylamine, tris[2-(2-methoxyethoxy)ethyl]amine, 1,8-diazabicyclo[5.4.0]undecene-7, 1,5-diazabicyclo[4.3.0]nonen-5, 7-methyl-1,5,7-triazabicyclo[4.4.0]deca-5-ene and 1,5,7-triazabicyclo[4.4.0]deca-5-ene.

The molecular weight of the basic compound (D) is preferably 17 to 500 and more preferably 100 to 350.

The content of the basic compound (D) is preferably 0.005 to 2 mass % and more preferably 0.05 to 0.9 mass %, based on the total mass of the polymer (A). From the viewpoint of the storage stability of the composition, it is also a preferred embodiment that the composition contains no basic compound (D).

### Surfactant (E)

The composition according to the present invention can contain a surfactant (E). When the composition contains the surfactant, the coatability can be improved. Examples of the surfactant that can be used in the present invention include (I) anionic surfactants, (II) cationic surfactants or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Megaface (DIC Corporation) and Surflon (AGC Inc.)), and organic siloxane surfactants (for example, KF-53 and KP341 (Shin-Etsu Chemical Co., Ltd.)).

These surfactants can be used alone or in combination of any two or more of these. The content of the surfactant (E) is 0.005 to 1 mass % and more preferably 0.01 to 0.1 mass %, based on the total mass of the polymer (A).

### Plasticizer (F)

The composition according to the present invention can further contain a plasticizer (F). By adding the plasticizer, film cracking can be suppressed.

Examples of the plasticizer (F) include an alkali-soluble vinyl polymer and an acid-dissociable group-containing vinyl polymer. More specific examples thereof include polyvinyl chloride, polystyrene, polyhydroxystyrene, polyvinyl acetate, polyvinyl benzoate, polyvinyl ether, polyvinyl butyral, polyvinyl alcohol, polyether ester, polyvinyl pyrrolidone, polyacrylic acid, polymethacrylic acid, polyacrylic acid ester, polyimide maleate, polyacrylamide, polyacrylonitrile, polyvinyl phenol, novolac, and copolymers thereof, and polyvinyl ether, polyvinyl butyral, and polyether ester are more preferable.

The content of the plasticizer (F) is preferably 0 to 5 mass % and more preferably 0 to 3 mass %, based on the total mass of the polymer (A). It is also a preferred embodiment of the present invention that the composition contains no plasticizer (F).

### Crosslinking Agent (G)

The composition according to the present invention can further contain a crosslinking agent (G). In the present invention, the crosslinking agent refers to a compound itself having a crosslinking function. The crosslinking agent is not particularly limited as long as it crosslinks the polymer (A) intramolecularly and/or between the molecules.

Examples of the crosslinking agent include melamine compounds, guanamine compounds, glycoluril compounds or urea compounds substituted by at least one group selected from a methylol group, an alkoxymethyl group and an acyloxymethyl group; epoxy compounds; thioepoxy compounds; isocyanate compounds; azide compounds; and compounds containing a double bond such as an alkenyl ether group. Compounds containing a hydroxy group can also be used as the crosslinking agent.

Examples of the epoxy compound include tris(2,3-epoxypropyl)isocyanurate, trimethylolmethane triglycidyl ether, trimethylolpropane triglycidyl ether and triethylolethane triglycidyl ether. Examples of the melamine compound include compounds derived by methoxymethylation of 1 to 6 methylol groups of hexamethylolmelamine, hexamethoxymethylmelamine or hexamethylolmelamine, and mixtures thereof; and compounds derived by acyloxymethylation of 1 to 6 methylol groups of hexamethoxyethylmelamine, hexaacyloxymethylmelamine or hexamethylolmelamine, and mixtures thereof.

Examples of the guanamine compound include compounds derived by methoxymethylation of 1 to 4 methylol groups of tetramethylolguanamine, tetramethoxymethyl-guanamine or tetramethylolguanamine, and mixtures thereof; and compounds derived by acyloxymethylation of 1 to 4 methylol groups of tetramethoxyethylguanamine, tetraacyloxyguanamine or tetramethylolguanamine, and mixtures thereof.

Examples of the glycoluril compound include compounds derived by methoxymethylation of 1 to 4 methylol groups of tetramethylolglycoluril, tetramethoxyglycoluril, tetramethoxymethylglycoluril or tetramethylolglycoluril, and mixtures thereof; and compounds derived by acyloxymethylation of 1 to 4 methylol groups of tetramethylolglycoluril, and mixtures thereof.

Examples of the urea compound include compounds derived by methoxymethylation of 1 to 4 of methylol groups of tetramethylolurea, tetramethoxymethylurea or tetramethylolurea, and mixtures thereof; tetramethoxyethylurea, and the like.

Examples of the compound containing an alkenyl ether group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, trimethylolpropane trivinyl ether, and the like.

Examples of the crosslinking agent containing a hydroxy group include the following:

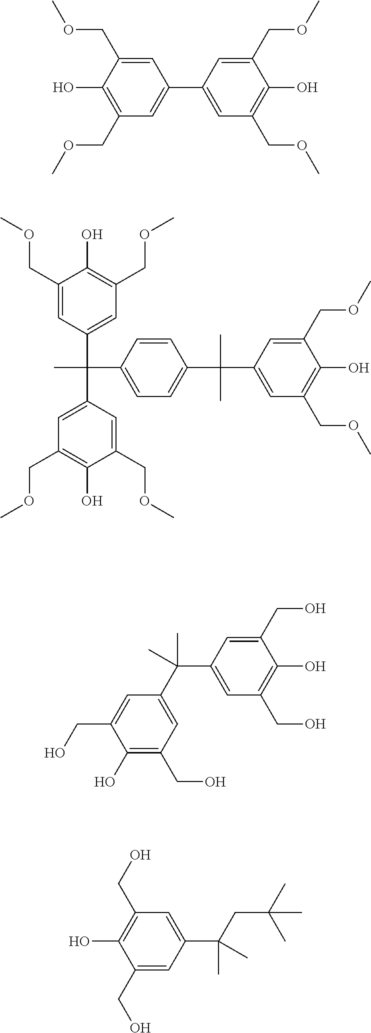

The crosslinking agent (G) can be used alone or in combination of any two or more of these.

The content of the crosslinking agent (G) is preferably 0 to 30 mass % and more preferably 0 to 20 mass %, based on the total mass of the polymer (A).

When the composition according to the present invention is a positive type, the content of the crosslinking agent (G) is preferably 0 to 5 mass %, more preferably 0 to 1.0 mass %, and further preferably 0 to 0.1 mass %, based on the total mass of the polymer (A). When the composition according to the present invention is a positive type, it is also a preferred embodiment of the present invention that the composition contains none of the crosslinking agent (G).

When the composition according to the present invention is a negative type, the content of the crosslinking agent (G) is preferably 3 to 30 mass %, more preferably 5 to 20 mass %, and further preferably 5 to 12 mass %, based on the total mass of the polymer (A).

### Additive (H)

The composition according to the present invention can further contain an additive (H) other than the components (A) to (G). The additive (H) is preferably a polymer other than the polymer (A), a photoreactive quencher, a surface smoothing agent, a contrast enhancer, an acid, a dye, a radical generator, a substrate adhesion enhancer, an antifoaming agent, or any combination of any of these.

The content of the additive (H) (in the case of a plurality, the sum thereof) is preferably 0 to 5 mass %, more preferably 0 to 3 mass %, and further preferably 0 to 1 mass %, based on the total mass of the polymer (A). It is also a preferred embodiment of the present invention that the composition according to the present invention contains no additive (H).

### Sulfonyloxyimide Compound (I)

The composition according to the present invention can further contain a sulfonyloxyimide compound (I) represented by Formula (I-1).

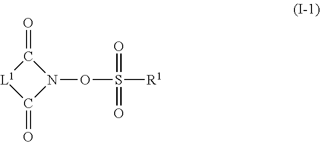

wherein
   Lⁱ is alkylene, arylene, or alkoxylene, and
   Rⁱ is alkyl, aryl, halogen-substituted alkyl, or halogen-substituted aryl.
   The content of the sulfonyloxyimide compound (I) is preferably 0 to 0.5 mass %, more preferably 0 to 0.1 mass %, and further preferably 0 to 0.01 mass %, based on the total mass of the polymer (A). It is also a preferred embodiment of the present invention that the composition does not contain the sulfonyloxyimide compound (I).

### Carboxylic Acid Ester (J)

The composition according to the present invention can further contain a carboxylic acid ester (J) represented by Formula (J-1).

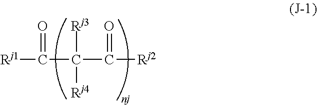

wherein
   R^{j1} is C₁₋₁₀ alkyl or —OR^{j1′},
   R^{j2} is —OR^{j2′},
   R^{j1′} and R^{j2′} are each independently C₁₋₂₀ hydrocarbon,
   R^{j3} and R^{j4} are each independently H or C₁₋₁₀ alkyl,
   R^{j1} and R^{j3} or R^{j4}, or R^{j2} and R^{j3} or R^{j4} can be bonded to each other to form a saturated or unsaturated hydrocarbon ring, and
   nj is 1 or 2,
   provided that when nj is 1, at least one of R^{j1} or R^{j1′}, and R^{j2′} is C₃₋₂₀ hydrocarbon.
   The content of the carboxylic acid ester (J) is preferably 0 to 2 mass %, more preferably 0 to 1 mass %, and further preferably 0 to 0.1 mass %, based on the total mass of the polymer (A). It is also a preferred embodiment of the present invention that the composition does not contain the carboxylic acid ester (J) (0%).

The present invention relates to use of the above-described composition for suppressing standing wave, improving resolution, improving rectangularity, and/or improving heat resistance.

### Method for Manufacturing Resist Pattern

A method for manufacturing a resist pattern according to the present invention includes steps below:
(1) applying the above-described composition directly onto a substrate;
(2) heating the composition to form a resist layer;
(3) exposing the resist layer;
(4) post exposure baking the resist layer; and
(5) developing the resist layer.

The numbers in parentheses indicate the order of the steps. For example, when the steps (1), (2) and (3) are described, the order of the steps is as described above.

The composition according to the present invention is applied directly onto a substrate (for example, a silicon/silicon dioxide coated substrate, a silicon nitride substrate, a silicon wafer substrate, a glass substrate, an ITO substrate, and the like) by an appropriate method. In the present invention, a case where a bottom anti-reflective coating is formed on the substrate is not included. The application method is not particularly limited, and examples thereof include a coating method using a spinner or a coater.

After the application of the composition, a resist layer is formed by heating (prebaking). The formation of the resist layer is performed, for example, by a hot plate. The heating temperature is preferably 80 to 250° C., more preferably 80 to 200° C., and further preferably 90 to 180° C. The heating time is preferably 30 to 600 seconds, more preferably 30 to 300 seconds, and further preferably 60 to 180 seconds. The heating is preferably performed in an air or a nitrogen gas atmosphere.

The film thickness of the resist layer varies depending on the wavelength of irradiation light, but is preferably 50 to 10,000 nm, more preferably 200 to 3,000 nm, and further preferably 200 to 2,000 nm.

The resist layer is exposed through a predetermined mask. The wavelength of the light to be used for the exposure is not particularly limited, but it is preferable to expose with light having a wavelength of 13.5 to 365 nm. Specifically, i-line (wavelength: 365 nm), KrF excimer laser (wavelength: 248 nm), ArF excimer laser (wavelength: 193 nm), extreme ultraviolet ray (wavelength: 13.5 nm) and the like can be used, and preferred one is KrF excimer laser. These wavelengths allow a range of ±1%. After exposure, post exposure bake can be performed, as necessary. The post exposure baking temperature is preferably 80 to 150° C., more preferably 100 to 140° C., and the heating time is 0.3 to 5 minutes, preferably 0.5 to 2 minutes.

After exposure, the resist layer is developed using a developer. The developer to be used is preferably a tetramethylammonium hydroxide (TMAH) aqueous solution of 2.38 mass %. The temperature of the developer is preferably 5 to 50° C. and more preferably 25 to 40° C., and the development time is preferably 10 to 300 seconds and more preferably 30 to 90 seconds. To these developers, for example, a surfactant can also be added.

The resist layer of the exposed region is removed by development in the case of using a positive type resist composition, and the resist layer of the unexposed region is removed by development in the case of using a negative type resist composition, thereby forming a resist pattern. The resist pattern can also be further made finer, for example, using a shrink material.

In both the positive type and the negative type of the resist pattern to be formed, the influence of standing wave is reduced, and the pattern side portion has a smooth shape.

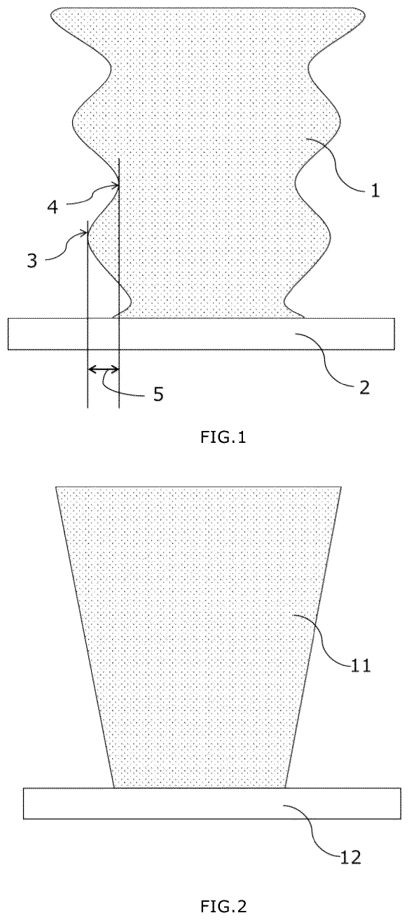

FIG. 1 is a schematic diagram illustrating the cross-sectional shape of a negative type resist pattern when affected by standing wave. A resist pattern 1 is formed on a substrate 2. When a waveform having a large amplitude is formed in the cross-section in this way, the resist top shape greatly fluctuates with a slight difference in film thickness, and the dimensional accuracy deteriorates, so that it is preferable that such an amplitude is smaller. Upward from the point where the substrate and the resist pattern are in contact with each other, the first point where the width of the resist pattern becomes maximum is set as an antinode 3, and the point immediately above it where the width of the resist pattern is the minimum is set as a node 4. The distance between the antinode and the node in the direction parallel to the substrate is referred to as an internode distance 5. It is preferable that the internode distance is smaller, and particularly, the internode distance/desired pattern width (hereinafter referred to as a standing wave index) is preferably less than 10% and more preferably 5% or less. The desired pattern width can be the width of the top of the resist when it is assumed not to be affected by standing wave. Undesired shape and pattern collapse, which is caused due to formation of a notch, are suppressed and stable formation of a finer pattern is facilitated by reducing standing wave that appears in the resist pattern.

FIG. 2 is a schematic diagram illustrating a cross-sectional shape of a negative type resist pattern when not affected by standing wave. In the negative type resist, since the polymer is insolubilized through the acid generated by the exposure, the lower part is less insolubilized than the upper part because it is difficult for light to reach the lower part and the acid is generated less than in the upper part. Therefore, the formed pattern tends to have a reverse tapered shape. In FIG. 2, neither antinode nor node exists, and in this case, the standing wave index is considered to be zero.

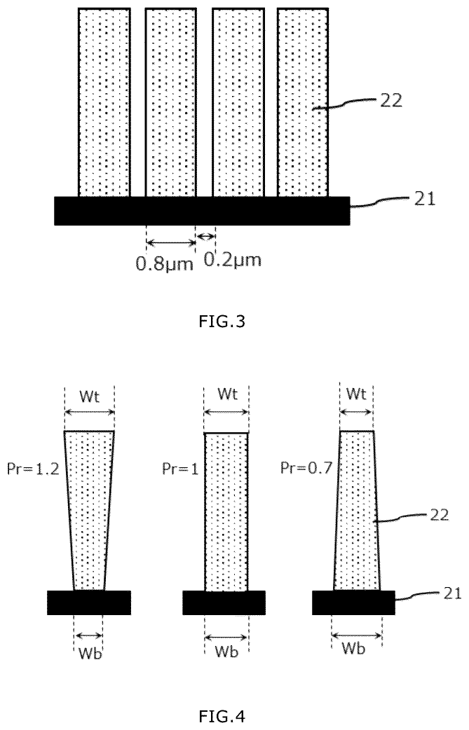

FIGS. 3 and 4 schematically illustrate a vertical cross-section of a trench pattern 22 on a substrate 21. Wt is the width of the top portion of the pattern, and Wb is the width of the bottom portion of the pattern. This ratio Pr is defined as Pr=Wt/Wb. When a positive type resist is used and the resist pattern is a trench pattern having a film thickness of 1.5 μm, a line width of 0.8 μm, and a space width of 0.2 μm, 0.7≤Pr≤1.2 is preferably satisfied, and 0.8≤Pr≤1.1 is more preferably satisfied.

Preferably, a resist pattern to be manufactured has a reverse tapered shape. The resist pattern can be suitably used in a lift-off step.

A method for manufacturing a metal pattern according to the present invention includes:
manufacturing a resist pattern by the above-described method;
(6a) forming a metal layer on the resist pattern; and
(7a) removing the remaining resist pattern and the metal layer on the resist pattern. Subsequent to the steps (1) to (5), the steps (6a) and (7a) are carried out. The order of the steps is as described above.

The metal layer is formed, for example, by vapor deposition or spattering of a metal such as gold or copper (which can be a metal oxide or the like). Subsequently, the metal pattern can be formed by removing the resist pattern together with the metal layer formed on the upper part of the resist pattern, using a stripper. The stripper is not particularly limited as long as it is one used as a stripper for resist, and for example, N-methylpyrrolidone (NMP), acetone, or an alkaline solution is used.

When the resist according to the present invention is a negative type, the resist tends to have a reverse tapered shape as described above. In the case of the reverse tapered shape, there is a space between the metal on the resist pattern and the metal formed on the region where the resist pattern is not formed, so that the resist pattern can be easily removed.

The film thickness of the metal pattern to be formed is preferably 10 to 70,000 nm. The film thickness of the metal pattern is preferably 5 to 70%, more preferably 10 to 70%, and further preferably 25 to 50%, with respect to the resist film thickness.

A method for manufacturing a pattern substrate according to the present invention, includes:
manufacturing a resist pattern by the above-described method;
(6b) etching using the resist pattern as a mask; and
(7b) processing a substrate.
The etching can be either dry etching or wet etching, and the etching can be performed a plurality of times. Subsequent to the steps (1) to (5), the steps (6b) and (7b) are carried out.

A method for manufacturing a pattern substrate according to the present invention, includes:
manufacturing a resist pattern by the above-described method;
(6c) etching the resist pattern; and
(7c) etching a substrate.
Subsequent to the steps (1) to (5), the steps (6c) and (7c) are carried out. The order of the steps is as described above.

A combination of the steps (6c) and (7c) is repeated at least twice or more; and the substrate includes a laminate of a plurality of Si-containing layers, in which at least one Si-containing layer is conductive and at least one Si-containing layer is electrically insulative.

Preferably, the conductive Si-containing layers and electrically insulative Si-containing layers are alternately laminated. The film thickness of the resist layer formed in (2) is preferably 0.5 to 200 μm.

The resist pattern according to the present invention can also be used for ion implantation. Therefore, the method for manufacturing a processed substrate according to the present invention includes steps below:
manufacturing a resist pattern by the above-described method; and
performing an ion implantation using the resist pattern as a mask, or
processing an underlayer of the resist pattern using the resist pattern as a mask to form an underlayer pattern, and
performing an ion implantation using the underlayer pattern as a mask.

The ion implantation can be performed by a known method using a known ion implantation apparatus. In the manufacture of semiconductor devices, liquid crystal display devices and the like, forming an impurity diffusion layer on a substrate surface is conducted. The formation of an impurity diffusion layer is usually performed in two stages of impurity introduction and diffusion thereof. As one method of the introduction, there is an ion implantation in which impurities such as phosphorus and boron are ionized in a vacuum, accelerated in a high electric field and implanted into the support surface. As the ion acceleration energy during ion implantation, an energy load of 10 to 200 keV is generally applied to the resist pattern, which can destroy the resist pattern.

Since the resist pattern formed according to the present invention is a thick film, has high rectangularity, and has high heat resistance, the resist pattern can be suitably used for ion implantation applications in which ions are implanted at high energy.

Ion sources (impurity elements) include ions such as boron, phosphorus, arsenic, and argon. Thin films on substrates include silicon, silicon dioxide, silicon nitride, aluminum, and the like.

Subsequently, if necessary, the substrate is further processed to form a device. Known methods can be applied to this further processing. The method for manufacturing a device according to the present invention includes either of the above-described method, and preferably, a step of forming a wiring on the processed substrate is further comprised. Examples of the device include a semiconductor device, a liquid crystal display device, an organic EL display device, a plasma display device, and a solar cell device, and a semiconductor device is preferable.

### EXAMPLES

The present invention is described below with reference to various examples. The embodiment of the present invention is not limited only to these examples.

### Preparation of Composition of Example 1

PGME and EL are mixed at a mass ratio of 70:30 to obtain a mixed solvent. 100 mass parts of polymer 1, 1.50 mass part of photoacid generator 1, 0.3 mass parts of basic compound 1, and 0.06 mass parts of surfactant 1 are added to a mixed solvent, so that the solid content concentration becomes 18.0 mass %. The solid content concentration means the concentration of all components other than the solvent (including the mixed solvent) contained in the composition in entire composition. The resultant is stirred for 30 minutes at room temperature. It is visually checked that the added materials are dissolved. The resultant is filtered through a 0.05 μm filter. Thereby, a composition of Example 1 is obtained.

Polymer 1: Hydroxystyrene:styrene:t-butyl acrylate copolymer, molar ratio 6:2:2, Mw: 12,000, the above ratio indicates the constituent ratio of each repeating unit. The same applies hereinafter.

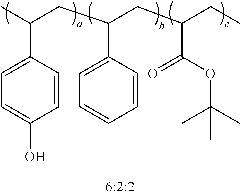

Photoacid generator 1

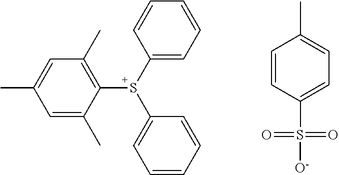

Basic compound 1: tris[2-(2-methoxyethoxy)ethyl]amine
Surfactant 1: MEGAFACE R-40, DIC Corporation

### Preparation of Compositions of Examples 2 to 5 and Composition of Comparative Example 1

Compositions of Examples 2 to 5 and a composition of Comparative Example 1 are obtained in the same manner as in “Preparation of composition of Example 1”, except that the photoacid generator (B) is changed to components shown in Table 1.

TABLE 1

| | | | | | | Heat |
|---|---|---|---|---|---|---|
| | | Photoacid | Rectangu- | Standing | Reso- | resis- |
| | | generator (B) | larity | wave | lution | tance |
| Example | 1 | Photoacid | B | A | B | B |
| | | generator 1 | | | | |
| | 2 | Photoacid | A | B | A | A |
| | | generator 2 | | | | |
| | 3 | Photoacid | A | B | A | A |
| | | generator 3 | | | | |
| | 4 | Photoacid | A | B | A | A |
| | | generator 4 | | | | |
| | 5 | Photoacid | B | A | B | B |
| | | generator 5 | | | | |
| Comparative | 1 | Photoacid | A | C | B | A |
| Example | | generator 6 | | | | |

In the table,
Photoacid generator 2

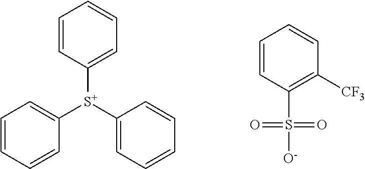 [SMILES: c1ccc([S+](c2ccccc2)c2ccccc2)cc1 ; O=S(=O)([O-])c1ccccc1C(F)(F)F]

Photoacid generator 3

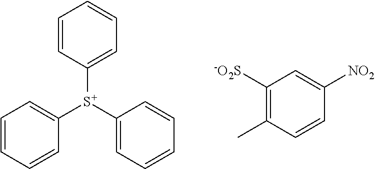

Photoacid generator 4

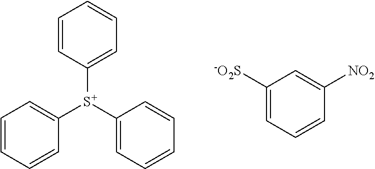

Photoacid generator 5

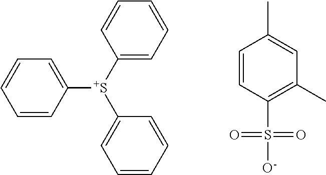 [SMILES: c1ccc([S+](c2ccccc2)c2ccccc2)cc1 ; Cc1ccc(S(=O)(=O)[O-])c(C)c1]

Photoacid generator 6

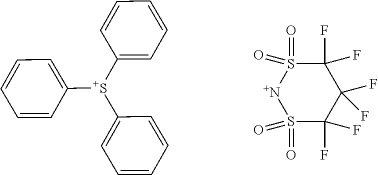 [SMILES: c1ccc([S+](c2ccccc2)c2ccccc2)cc1 ; O=S1(=O)[NH2+]S(=O)(=O)C(F)(F)C(F)(F)C1(F)F]

### Formation of Resist Pattern

Using a coater developer Mark 8 (Tokyo Electron Ltd.), each composition is dropped onto an 8 inch Si wafer and spin-coating is performed. This wafer is heated at 140° C. for 90 seconds using a hot plate under atmospheric conditions to form a resist layer. The film thickness of the resist layer at this point is 1.5 μm when measured by an optical interference type film thickness measuring device M-1210 (SCREEN).

This resist layer is exposed using a KrF stepper FPA3000-EX5 (Canon). The exposed wafer is heated (PEB) at 120° C. for 90 seconds using a hot plate under atmospheric conditions. Thereafter, this resist layer is puddle-developed with a 2.38 mass % TMAH aqueous solution for 60 seconds, washed with water, and spin-dried at 1,000 rpm. Thereby, a trench pattern with a line width of 0.8 μm and a space width of 0.2 μm is formed. The line width and the space width are values measured at the bottom portion of the pattern.

FIG. 3 schematically illustrates a shape of this pattern. The exposure amount with which the trench pattern having a line width of 0.8 μm and a space width of 0.2 μm is formed is defined as an optimum exposure amount.

### Evaluation of Rectangularity

A section of the substrate formed in “Formation of resist pattern” is formed and the vertical cross-section is observed with a scanning type electron microscope (SEM). Wt is the width of the top portion of the resist pattern, Wb is the width of the bottom portion of the resist pattern, and a ratio Pr is Pr=Wt/Wb, evaluation is performed according to the following criteria. The evaluation results are described in Table 1.

A: 0.8≤Pr≤1.2,
B: 0.7≤Pr<0.8,
C: Pr>1.2 or Pr<0.7

### Evaluation of Standing Wave

The internode distance of standing wave of the resist pattern formed in the above “Evaluation of rectangularity” is evaluated according to the following criteria. The evaluation results are described in Table 1.
A: The internode distance is less than 10 nm,
B: The internode distance is 10 nm or more and less than 50 nm,
C: The internode distance is 50 nm or more

### Evaluation of Resolution

A resist pattern is formed in the same manner as in “Formation of resist pattern”, except that exposure is performed using a mask pattern having a space size of 0.25 to 0.16 μm with the optimum exposure amount described in “Formation of resist pattern”. The minimum dimension in which the resist pattern could be formed is defined as resolution (nm), and the resolution is evaluated according to the following criteria. The evaluation results are described in Table 1.
A: The resolution is 180 nm or less,
B: The resolution is more than 180 nm and less than 200 nm,
C: The resolution is 200 nm or more

### Evaluation of Heat Resistance

The substrate on which the resist pattern is formed by the method described in “Formation of resist pattern” is heated at 150° C. for 60 seconds using a hot plate. Thereafter, the change in the shape of the top portion of the resist pattern is observed in the vertical cross-section using an SEM, and evaluation is performed according to the following criteria. The evaluation results are described in Table 1.
A: No change in shape,
B: Change of less than 50 nm,
C: Change of 50 nm or more

### Reference Example: Formation of Resist Pattern in the Case of Having Bottom Anti-Reflective Coating

As a reference example, a case where a bottom anti-reflective coating is formed below a resist layer is evaluated. Since the present invention is a composition directly coating a substrate, a case where a bottom anti-reflective coating is formed on a substrate is outside the scope of the present invention.

A bottom anti-reflective coating forming composition AZ KrF-17B (Merck Electronics) is applied onto an 8 inch Si wafer and baked at 180° C. for 60 seconds to form a bottom anti-reflective coating (BARC) having a thickness of 45 nm. The composition of Example 1 or the composition of Comparative Example 1 is dropped onto the BARC and spin-coating is performed. Thereafter, the same operation as in the above “Formation of resist pattern” is performed.

When rectangularity, standing wave, resolution, and heat resistance are evaluated in the same manner as described above, the rectangularity is evaluated as “B” and the others are evaluated as “A” in the case of using each of both compositions.

In these cases, due to the presence of the BARC, a step of removing the BARC is required, which is not suitable for an implant step and a lift-off step.

### EXPLANATION OF SYMBOLS

1 Substrate
2 Resist pattern affected by standing wave
3 Antinode
4 Node
5 Internode distance
11 Substrate
12 Resist pattern not affected by standing wave
21 Substrate
22 Trench pattern

1. A substrate coating resist composition comprising:
a polymer (A); and
a photoacid generator (B),
wherein
the polymer (A) includes at least one of repeating units represented by Formulae (A-1) and (A-2), and optionally further includes at least one of repeating units represented by Formulae (A-3) and (A-4), and
the photoacid generator (B) is represented by Formula (B-1), 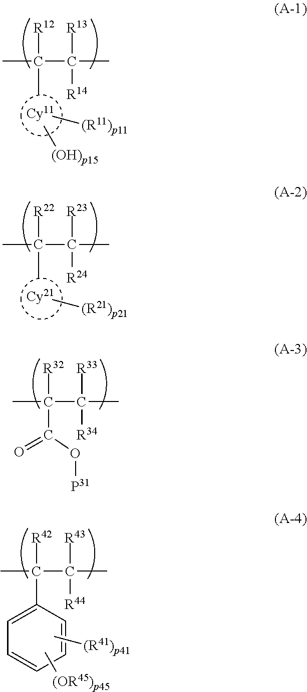
wherein
C_{y}¹¹ and C_{y}²¹ are each independently aryl or heteroaryl having 5 or 6 ring atoms,
R¹¹, R²¹, R⁴¹, and R⁴⁵ are each independently C₁₋₅ alkyl (wherein methylene in the alkyl can be replaced with oxy);
R¹², R¹³, R¹⁴, R²², R²³, R²⁴, R³², R³³, R³⁴, R⁴², R⁴³, and R⁴⁴ are each independently hydrogen, C₁₋₅ alkyl, C₁₋₅ alkoxy, or —COOH;
p11 is 0 to 4, p15 is 1 to 2, p11+p15≤5,
p21 is 0 to 5,
p41 is 0 to 4, p45 is 1 to 2, p41+p45≤5; and
P³¹ is C₄₋₂₀ alkyl (wherein some or all of alkyl can form a ring, some or all of H of the alkyl can be substituted with halogen, and methylene in the alkyl can be replaced with oxy or carbonyl);
Bⁿ⁺ cation Bⁿ⁻ anion (B-1)
wherein
Bⁿ⁺ cation is n-valent as a whole, Bⁿ⁻ anion is n-valent as a whole, n is 1 to 3, and
Bⁿ⁻ anion is an anion represented by Formula (BA-1) 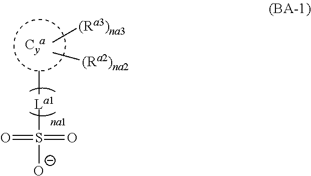
wherein
C_{y}^{a} is a hydrocarbon ring having 5 or 6 ring atoms, and one of the ring atoms can be replaced with nitrogen,
L^{a1} is C₁₋₅ alkylene,
R^{a2} is nitro or cyano,
R^{a3} is unsubstituted or fluorine-substituted C₁₋₁₀ alkyl,
na1 is 0 or 1,
na2 is a number of 0 to 3, and
na3 is a number of 0 to 3.

2. The composition according to claim 1, wherein Bⁿ⁺ cation is selected from the group consisting of a cation represented by Formula (BC-1), a cation represented by Formula (BC-2), and a cation represented by Formula (BC-3): 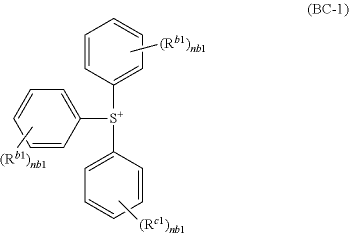
wherein
R^{b1} is each independently C₁₋₆ alkyl, C₁₋₆ alkoxy, C₆₋₁₂ aryl, C₆₋₁₂ arylthio, or C₆₋₁₂ aryloxy,
nb1 is each independently 0, 1, 2, or 3, 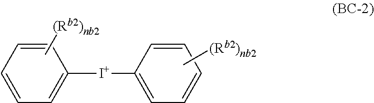
wherein
R^{b2} is each independently C₁₋₆ alkyl, C₁₋₆ alkoxy, or C₆₋₁₂ aryl, and
nb2 is each independently 0, 1, 2, or 3, and 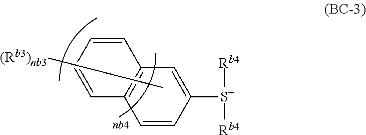
wherein
R^{b3} is each independently hydroxy, C₁₋₆ alkyl, C₁₋₆ alkoxy, or C₆₋₁₂ aryl,
R^{b4} is each independently C₁₋₆ alkyl, provided that, two R^{b4} can be bonded to each other to form a ring structure,
nb3 is each independently 0, 1, 2, or 3, and
nb4 is 0 or 1.

3. The composition according to claim 1, wherein n_{A-1}, n_{A-2}, n_{A-3} and n_{A-4}, which are the numbers of repeating units represented by Formulae (A-1), (A-2), (A-3), and (A-4) in the polymer (A), satisfy the following:
n_{A-1}/(n_{A-1}+n_{A-2}+n_{A-3}+n_{A-4})=0 to 100%,
n_{A-2}/(n_{A-1}+n_{A-2}+n_{A-3}+n_{A-4})=0 to 100%,
n_{A-3}/(n_{A-1}+n_{A-2}+n_{A-3}+n_{A-4})=0 to 50%, or
n_{A-4}/(n_{A-1}+n_{A-2}+n_{A-3}+n_{A-4})=0 to 50%,
further wherein nₜₒₜₐₗ, which is the total number of all repeating units included in the polymer (A), satisfies the following:
(n_{A-1}+n_{A-2}+n_{A-3}+n_{A-4})/nₜₒₜₐₗ=80 to 100%, or
and further wherein a mass average molecular weight Mw of the polymer (A) is 3,000 to 50,000.

4. The composition according to claim 1, further comprising a solvent (C) selected from the group consisting of propylene glycol monomethyl ether, propylene glycol monomethyl ether acetate, ethyl lactate, n-butyl acetate, n-butyl ether, 2-heptanone, cyclohexanone, or any combination thereof, wherein the content of the solvent (C) is 50 to 90 mass % based on the total mass of the composition.

5. The composition according to claim 1, further comprising a basic compound (D) selected from the group consisting of ammonia, a C₁₋₁₆ primary aliphatic amine compound, a C₂₋₃₂ secondary aliphatic amine compound, a C₃₋₄₈ tertiary aliphatic amine compound, a C₆₋₃₀ aromatic amine compound, a C₅₋₃₀ heterocyclic amine compound, or any combination thereof, wherein the content of the basic compound (D) is 0.01 to 5 mass % based on the total mass of the polymer (A).

6. The composition according to claim 1, further comprising a surfactant (E) wherein the content of the surfactant (E) is 0.005 to 1 mass % based on the total mass of the polymer (A).

7. The composition according to claim 1, further comprising a plasticizer (F) wherein the content of the plasticizer (F) is 0 to 0.5 mass % based on the total mass of the polymer (A), and
optionally, the composition further comprises a crosslinking agent (G) wherein the content of the crosslinking agent (G) is 0 to 30 mass % based on the total mass of the polymer (A).

8. The composition according to claim 1, further comprising an additive (H) selected from the group consisting of a polymer other than the polymer (A), a photoreactive quencher, a surface smoothing agent, a contrast enhancer, an acid, a dye, a radical generator, a substrate adhesion enhancer, an antifoaming agent, or any combination thereof, wherein the content of the additive (H) is 0 to 5% based on the total mass of the polymer (A).

9. The composition according to claim 1, further comprising a sulfonyloxyimide compound (I) represented by Formula (I-1) and at a content of 0 to 0.5 mass % based on the total mass of the polymer (A), 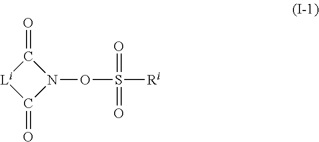
wherein
Lⁱ is alkylene, arylene, or alkoxylene, and
Rⁱ is alkyl, aryl, halogen-substituted alkyl, or halogen-substituted aryl.

10. The composition according to claim 1, further comprising a carboxylic acid ester (J) represented by Formula (J-1) and at a content of 0 to 2 mass % based on the total mass of the polymer (A), 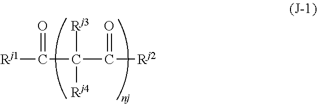
wherein
R^{j1} is C₁₋₁₀ alkyl or —OR^{j1}′,
R^{j2} is —OR^{j2}′,
R^{j1}′ and R^{j2}′ are each independently C₁₋₂₀ hydrocarbon,
R^{j3} and R^{j4} are each independently H or C₁₋₁₀ alkyl,
R^{j1} and R^{j3} or R^{j4}, or R^{j2} and R^{j3} or R^{j4} can be bonded to each other to form a saturated or unsaturated hydrocarbon ring, and
nj is 1 or 2,
provided that when nj is 1, at least one of R^{j1} or R^{j1}′, and R^{j2}′ is C₃₋₂₀ hydrocarbon.

11. The composition according to claim 1, wherein the content of the polymer (A) is 10 to 40 mass % based on the total mass of the composition, and the content of the photoacid generator (B) is 0.2 to 5 mass % based on the total mass of the polymer (A).

12. The composition according to claim 1, wherein the composition is a substrate coating chemically amplified resist composition.

13. A method for manufacturing a resist pattern, comprising:
(1) applying the composition according to claim 1 directly onto a substrate;
(2) heating the composition to form a resist layer;
(3) exposing the resist layer;
(4) post exposure baking the resist layer; and
(5) developing the resist layer.

14. The method according to claim 13, wherein
light having a wavelength of 13.5 to 365 nm is used for the exposing in (3),
a film thickness of the resist layer formed in (2) is 50 to 10,000 nm, and
a resist pattern to be manufactured has a reverse tapered shape.

15. The method according to claim 13, wherein, in a case of the resist pattern being a trench pattern having a film thickness of 1.5 μm, a line width of 0.8 μm, and a space width of 0.2 μm, when a width of a top portion of the pattern and a width of a bottom portion of the pattern in the trench pattern are designated as Wt and Wb, respectively, 0.7≤Wt/Wb≤1.2 is satisfied.

16. A method for manufacturing a metal pattern, comprising:
manufacturing a resist pattern by the method according to claim 13;
(6a) forming a metal layer on the resist pattern; and
(7a) removing the remaining resist pattern and the metal layer on the resist pattern.

17. A method for manufacturing a pattern substrate, comprising:
manufacturing a resist pattern by the method according to claim 13;
(6b) etching using the resist pattern as a mask; and
(7b) processing a substrate.

18. A method for manufacturing a pattern substrate, comprising:
forming a resist pattern by the method according to claim 13;
(6c) etching the resist pattern; and
(7c) etching a substrate:
wherein
a combination of the steps (6c) and (7c) is repeated at least twice; and the substrate includes a laminate of a plurality of Si-containing layers, in which at least one Si-containing layer is conductive and at least one Si-containing layer is electrically insulative.

19. A method for manufacturing a processed substrate, comprising:
manufacturing a resist pattern by the method according to claim 13; and
performing an ion implantation using the resist pattern as a mask, or
processing an underlayer of the resist pattern using the resist pattern as a mask to form an underlayer pattern, and performing an ion implantation using the underlayer pattern as a mask.

20. A method for manufacturing a device, comprising the method according to claim 13, and forming a wiring on the processed substrate.
